(19) United States
(12) Patent Application Publication
(10) Pub. No.: US 2005/0270865 A1
(43) Pub. Date: Dec. 8, 2005

(54) Test apparatus with memory data converter for redundant bit and word lines

(75) Inventors: Sven Boldt, Aschheim (DE); Manfred Moser, Dachau (DE); Erwin Thalmann, Villach (AT); Thomas Neyer, Villach (AT)

Correspondence Address: Maginot, Moore & Beck;Bank One Tower, Suite 3000, 111 Monument Circle, Indianapolis, IN, 46204, US

(73) Assignee: Infineon Technologies AG, Munchen (DE)

(21) Appl. No.: 11/138,653

(22) Filed: May 26, 2005

(30) Foreign Application Priority Data
May 27, 2004 (DE) 10 2004 025 893.7

(51) Int. Cl. G11C 7/00

(52) U.S. Cl. 365/200

(57) ABSTRACT

The invention provides a test apparatus for testing an electronic circuit device (101) to be tested by means of a test system (100), having an interface unit (102) for connecting the circuit device (101) to be tested to the test system (100), an address decoding unit (107) for decoding external addressing data (104) input by means of the test system (100) into internal addressing data (110, 112) and for addressing memory cells of a memory cell array (108) of the circuit device (101) to be tested with the internal addressing data (110, 112), and a memory data converter (115) for converting logical memory data (106), which are fed by the test system (100), into physical memory data (114). The memory data converter (115) carries out a conversion of the logical memory data (106) fed by the test system (100) into physical memory data (114) in a manner dependent on the internal addressing data (110, 112) of the circuit device (101) to be tested.

The present invention generally relates to a test apparatus for testing circuit devices to be tested with predeterminable test modes.

In particular, the present invention relates to a test apparatus for testing an electronic circuit unit to be tested by means of a test system, the test apparatus and the electronic circuit device to be tested having an interface unit for connecting the circuit device to be tested to the test system, an address decoding unit for decoding external addressing data input by means of the test system into internal addressing data and for addressing memory cells of a memory cell array of the circuit device to be tested with the internal addressing data and a memory data converter for converting logical memory data, which are fed to the electronic circuit device to be tested by the test system, into physical memory data.

When testing electronic circuit devices to be tested, it is important in particular to keep test costs low. Such test costs result from a number of electronic circuit devices to be tested which can be tested in a predetermined time, i.e. from a throughput rate of the electronic circuit devices to be tested. In order to lower test costs, it is either possible to reduce the test times per electronic circuit device to be tested or it is possible to increase the number of circuit units to be tested which can be tested in parallel and can be tested simultaneously by means of a test system.

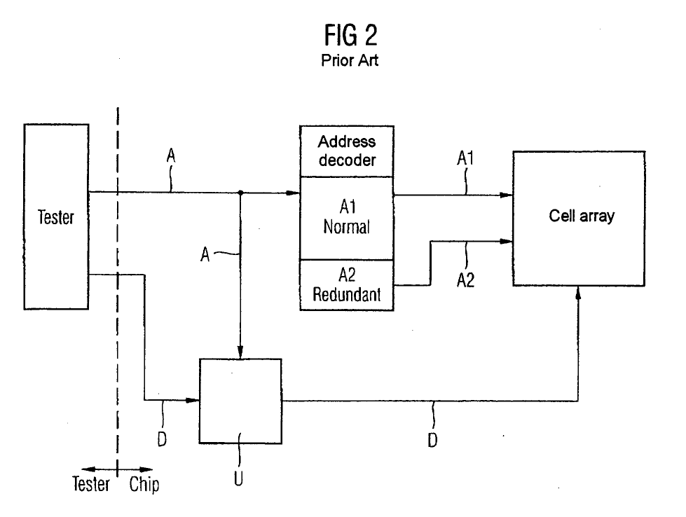

FIG. 2 shows a conventional test apparatus for testing a memory module (chip). A tester is connected to the memory module (the circuit device to be tested) via address lines A and data lines D. The electronic circuit device to be tested has an address decoder and a cell array, inter alia. In this case, the address decoder comprises two regions A1 and A2. A1 represents the address range for conventional memory cells addressed by means of unaltered bit and/or word lines.

The region A2 of the address decoder serves for diverting addresses onto a redundant bit and/or word line if a bit and/or word line currently being addressed is defective. Consequently, proceeding from the addressing signal on the address line A, two addressing signals A₁ and A₂ are fed to the cell array downstream of the address decoder in order to address memory cells in the memory cell array (cell array). Since, in the case of defective bit and/or word lines, the address decoder automatically diverts addressing data input externally via the address line A onto redundant address lines, externally no difference is apparent with regard to an addressing since a different bit and/or word line is merely used in the cell array.

An essential component when testing circuit devices to be tested in the test apparatus is a memory data converter U. The memory data converter U converts logical data into physical data, this conversion being effected in a manner dependent on a memory address. If logical data are written in a normal mode, by way of example, then these logical data do not correspond to the physical data in the cell array.

If, by way of example, the entire cell array has logical “0” values written to it, this information is written in the cell array by means of physical “0” values and “1” values. A physical “0” is written on a “true” bit line, while a physical “1” is written on a complement bit line. Such division into true and complement bit lines is provided in the electronic circuit device to be tested for reasons of saving space in a design layout.

The memory data converter U ensures that physical data can be written. Depending on the address, the data are modified during writing and reading. If the aim is to write “0” values to the entire cell array, then physical “0” values are actually written on all true and complement bit lines.

In the test apparatus according to the prior art as shown by way of example in FIG. 2, problems arise, however, when a defective bit and/or word line is addressed, i.e. when an attempt is made to write onto a defective bit and/or word line. Such a defective bit and/or word line is exchanged in the address decoder (region A2) for a redundant bit and/or word line provided from the outset in order that the electronic circuit device to be tested remains fully functional.

However, the block diagram of a conventional test apparatus as shown in FIG. 2 clearly reveals that the memory data converter U cannot identify such a redundant line and therefore also cannot ensure that a testing of the electronic circuit device to be tested is carried out topologically correctly by the test system.

In a disadvantageous manner, the memory data converter U is only connected to external lines, i.e. to the external address line A and the external data line D and also, via a further data line D, to the cell array of the memory module.

This results in the disadvantage that when a repaired line (diverted address, diverted onto redundant line) is addressed, the address information of the original, defective line is then used for determining the topology. In particular, it is inexpedient that when a true line is replaced by a redundant complement line, the incorrect topology would then be mapped in the cell array.

This is disadvantageous in particular in the case of retention measurements, i.e. in the case of measurements concerning the discharging of the memory cells, since here it is necessary to write identical physical data in the entire cell array of the memory module. In an inexpedient manner, the memory data converter of the conventional test apparatus always uses a manipulation of data with external addresses.

Consequently, it is disadvantageous that when a redundant line is addressed, the memory data converter cannot identify this.

Therefore, it is an object of the present invention to provide a test apparatus in which, even after a diversion of addresses onto redundant lines, a correct test with an electronic circuit device to be tested is made possible in conjunction with short test times.

This object is achieved by means of a test apparatus for testing an electronic circuit device to be tested by means of a test system having the features of patent claim 1.

Furthermore, the object is achieved by means of a method specified in patent claim 4.

Further refinements of the invention emerge from the subclaims.

An essential concept of the invention consists in designing the memory data converter for converting the logical memory data fed by the test system into physical memory data in such a way that a memory data conversion is provided in a manner dependent on the internal addressing data of the circuit device to be tested. Consequently, it is essential to the invention that the memory data converter is only fed addressing data which are also actually used for storing or for reading memory data in or from the memory cell array, respectively.

This gives rise to the advantage that the memory data converter obtains an item of information for a change of memory data only from the cell array addresses that are actually used. In this case, in an expedient manner, it is unimportant for the memory data converter whether original or redundant (originally defective and repaired) lines are used in the electronic circuit device to be tested. In an advantageous manner, a data manipulation by means of the memory data converter is always effected on the basis of the bit and/or word lines actually used.

The test apparatus according to the invention for testing an electronic circuit device to be tested by means of a test system essentially has:
a) an interface unit for connecting the circuit device to be tested to the test system;
b) an address decoding unit for decoding external addressing data input by means of the test system into internal addressing data and for addressing memory cells of a memory cell array of the circuit device to be tested with the internal addressing data; and
c) a memory data converter for converting logical memory data, which are fed by the test system, into physical memory data, the memory data converter for converting the logical memory data fed by the test system into physical memory data being designed in such a way as to provide a memory data conversion in a manner dependent on the internal addressing data of the circuit device to be tested.

Furthermore, the method according to the invention for testing an electronic circuit device to be tested by means of a test system essentially has the following steps of:
a) connecting the circuit device to be tested to the test system by means of an interface unit;
b) inputting external addressing data from the test system into the circuit device to be tested;
c) feeding logical memory data from the test system to the circuit device to be tested;
d) decoding the external addressing data that have been input into internal addressing data by means of an address decoding unit;
e) addressing memory cells of a memory cell array of the circuit device to be tested with the internal addressing data; and
f) converting the logical memory data fed by the test system into physical memory data by means of a memory data converter, the memory data converter for converting the logical memory data fed by the test system into physical memory data carrying out a memory data conversion in a manner dependent on the internal addressing data of the circuit device to be tested.

Advantageous developments and improvements of the respective subject matter of the invention are found in the subclaims.

In accordance with one preferred development of the present invention, the address decoding unit has a basic addressing section for addressing memory cells of the memory cell array with first internal addressing data, which relate to unaltered bit and/or word lines of the memory cell array, and a redundant addressing section for addressing memory cells of the memory cell array with second internal addressing data, which relate to used redundant bit and/or word lines of the memory cell array.

In accordance with a further preferred development of the present invention, the electronic circuit device to be tested is designed as a memory module.

In accordance with yet another preferred development of the present invention, the external addressing data are diverted onto redundant bit and/or word lines of the memory cell array by means of the redundant addressing section of the address decoding unit.

In accordance with yet another preferred development of the present invention, the memory data converter for converting the logical memory data fed by the test system into physical memory data is fed the first internal addressing data via a first internal address data line and the second internal addressing data via a second internal address data line.

In accordance with yet another preferred development of the present invention, the memory data converter for converting the logical memory data fed by the test system into physical memory data exchanges the physical memory data with the memory cell array of the circuit device to be tested via an internal memory data line.

In accordance with yet another preferred development of the present invention, the memory data converter for converting the logical memory data fed by the test system into physical memory data changes the physical memory data to be written or to be read in an address-dependent manner during writing or during reading, respectively.

An exemplary embodiment of the invention is illustrated in the drawing and is explained in more detail in the description below.

In the drawings:

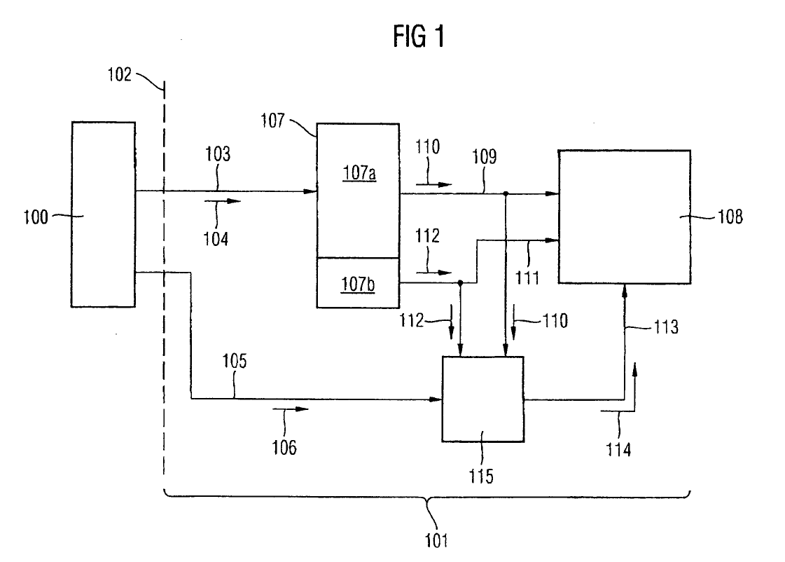

FIG. 1 shows a test apparatus in accordance with a preferred exemplary embodiment of the present invention; and

FIG. 2 shows a test apparatus according to the prior art.

FIG. 1 shows a block diagram of a test apparatus in accordance with a preferred exemplary embodiment of the present invention.

A reference symbol 101 denotes the region of the schematically illustrated electronic circuit device to be tested. The electronic circuit device 101 to be tested is connected to a test system 100 via an interface unit 102. The test system provides test modes, for example, and feeds external addressing data 104 and logical memory data 106 to the circuit device 101 to be tested. It should be pointed out that, for reasons of clarity of the illustration, only a transfer of addressing data and memory data between the test system 100 and the circuit device 101 to be tested will be discussed here. The external addressing data 104 are fed to an address decoding unit 107 of the circuit device 101 to be tested by the test system 100.

The address decoding unit 107 comprises a basic addressing section 107a and a redundant addressing section 107b. The basic addressing section 107a serves for a “normal” addressing of memory cells of a memory cell array via a first internal address data line 109. First internal addressing data 110, which are fed via the first internal address data line 109 from the basic addressing section 107a of the address decoding unit 107 to the memory cell array 108, are in this case conducted via current bit and/or word lines.

The redundant addressing section 107b of the address decoding unit 107 provides second internal addressing data 112, which are fed to the memory cell array 108 via a second internal address data line 111. These second internal addressing data 112 are required when it is ascertained that a bit and/or word line currently being addressed is defective, in such a way that said defective bit and/or word line is to be replaced by a redundant bit and/or word line. In the external addressing via the external address data line 103 using the external addressing data 104, no alteration arises, rather the external addressing data 104 are automatically diverted onto defect-free, redundant bit and/or word lines by the redundant addressing section 107b of the address decoding unit 107. Specifically, the external addressing data 104 are diverted onto redundant bit and/or word lines of the memory cell array 108 by means of the redundant addressing section 107b of the address decoding unit 107.

Furthermore, the test apparatus comprises a memory data converter 115 for converting the logical memory data 106 fed by the test system 100 into physical memory data 114.

Such a conversion of logical memory data 106 into physical memory data 114 is effected in a memory-address-dependent manner. If logical memory data 106 are written in a normal mode, then said logical memory 106 generally do not correspond to the physical memory data 114 in the memory cell array 108, as explained above.

The memory data converter 115 ensures that physical memory data 114 can be written correctly. In this case, the data are modified in a manner dependent on the address during writing and reading.

According to the invention, the memory data converter 115 for converting the logical memory data 106 fed by the test system 100 into physical memory data 114 is designed in such a way that a memory data conversion is provided in a manner dependent on the internal addressing data 110 or 112 of the circuit device 101 to be tested. The memory data converter 115 is fed the first internal addressing data 110, which relate to unaltered bit and/or word lines of the memory cell array 108, and the second internal addressing data 112, which relate to used redundant bit and/or word lines of the memory cell array 108.

The first internal addressing data 110 are fed to the memory data converter 112 via the first internal address data line 109, while the second internal addressing data 112 are fed to the memory cell array 108 via the second internal address data line 111. The memory data converter 115 feeds the converted physical memory data 114 to the memory cell array 108 via an internal memory data line 113.

By virtue of the invention's arrangement of the memory data converter with regard to the memory data flow downstream of the address decoding unit 107, comprising the basic addressing section 107a for addressing memory cells of the memory cell array 108 with the first internal addressing signals 110, which relate to unaltered bit and/or word lines of the memory cell array 108, and the redundant addressing section 107b for addressing memory cells of the memory cell array 108 with second addressing signals 112, which relate to used redundant bit and/or word lines of the memory cell array 108, there is the advantage that the memory module is always tested topologically correctly.

In an advantageous manner, it is additionally possible to obtain shorter test times since it is no longer necessary to assume that individual bit and/or word lines have been written to topologically incorrectly.

Consequently, it is advantageous that the memory data converter 115, in accordance with the invention's arrangement of the test apparatus, can detect a diversion of external addressing data 104 onto redundant bit and/or word lines, i.e. a transformation into the second internal addressing data 112, in such a way that the electronic circuit device 101 to be tested can be tested topologically correctly.

In an expedient manner, when testing the circuit device 101 to be tested, the addressing data can now be composed of “normal” addresses and redundant addresses.

With regard to the conventional test apparatus illustrated in FIG. 2, reference is made to the introduction to the description.

Although the present invention has been described above on the basis of preferred exemplary embodiments, it is not restricted thereto, but rather can be modified in diverse ways.

Moreover, the invention is not restricted to the application possibilities mentioned.

### LIST OF REFERENCE SYMBOLS

The figures, identical reference symbols designate identical or functionally identical components or steps.
100 Test system
101 Circuit device to be tested
102 Interface unit
103 External address data line
104 External addressing data
105 External memory data line
106 Logical memory data
107 Address decoding unit
107a Basic addressing section
107b Redundant addressing section
108 Memory cell array
109 First internal address data line
110 First internal addressing data
111 Second internal address data line
112 Second internal addressing data
113 Internal memory data line
114 Physical memory data
115 Memory data converter

1-9. (canceled)

10. An arrangement for testing an electronic circuit device using a test system, the arrangement comprising:
a) an interface configured to connect the electronic circuit device to the test system; and
b) an address decoding unit configured to decode external addressing data received from the test system into internal addressing data and to address memory cells of a memory cell array of the electronic circuit device with the internal addressing data; and
c) a memory data converter configured to convert logical memory data received from the test system into physical memory data, the memory data converter further configured to provide a memory data conversion in a manner dependent on the internal addressing data of the electronic circuit device.

11. The arrangement as claimed in claim 10, wherein the address decoding unit comprises:
a) a basic addressing section configured to address memory cells of the memory cell array with first internal addressing data corresponding to unaltered bit and/or word lines of the memory cell array; and
b) a redundant addressing section configured to address memory cells of the memory cell array with second internal addressing data corresponding to redundant bit and/or word lines of the memory cell array.

12. The arrangement as claimed in claim 10, wherein the interface is configured to connect the electronic circuit device in the form of a memory module to the test system.

13. A method for testing an electronic circuit device using a test system, the method comprising:
a) providing external addressing data from the test system into the electronic circuit device;
b) providing first data from the test system to the electronic circuit device;
c) decoding the external addressing data into internal addressing data;
d) addressing memory cells of a memory cell array of the circuit device to be tested with the internal addressing data; and
e) converting the first data into second data based on the internal addressing data of the electronic circuit device.

14. The method as claimed in claim 13, wherein step c) further comprises:
c1) addressing memory cells of the memory cell array with first internal addressing data corresponding to unaltered lines of the memory cell array; and
c2) addressing memory cells of the memory cell array with second internal addressing data corresponding to redundant lines of the memory cell array.

15. The method as claimed in claim 14, wherein step c2) further comprises converting at least some of the external addressing data into second internal addressing data because of faults in accessing at least some memory cells of the memory cell array.

16. The method as claimed in claim 15, wherein step e) further comprises using a memory data converter to convert the first data into second memory data based on the internal addressing data of the circuit device.

17. The method of claim 16, where step e) further comprises providing the memory data converter the first internal addressing data via a first internal address data line and the second internal addressing data via a second internal address data line.

18. The method as claimed in claim 13, further comprising providing the second data to the memory cell array via an internal memory data line.

19. The method as claimed in claim 13, wherein step e) further comprises changing some of the first data to generate the second data, based on the internal addressing data.

20. An arrangement for testing an electronic circuit device using a test system, the arrangement comprising:
a) an address decoding unit configured to decode external addressing data received from the test system into internal addressing data and to address memory cells of a memory cell array of the electronic circuit device with the internal addressing data; and
b) a memory data converter configured to convert first data received from the test system into second data, the memory data converter further configured to provide a memory data conversion in a manner dependent on the internal addressing data of the electronic circuit device.

21. The arrangement as claimed in claim 20, wherein there first data is memory test data.

22. The arrangement as claimed in claim 20, wherein the address decoding unit comprises:
a) a basic addressing section configured to address memory cells of the memory cell array with internal addressing data corresponding to first lines of the memory cell array; and
b) a redundant addressing section configured to address memory cells of the memory cell array with internal addressing data corresponding to redundant lines of the memory cell array.

23. The arrangement as claimed in claim 22, further comprising a first data line coupled between the basic addressing section and the memory cell array and a second data line coupled between the redundant addressing section and the memory cell array.

24. The arrangement as claimed in claim 23, wherein the memory data converter is operably coupled to the first data line and the second data line.

25. The arrangement of claim 20, wherein the first data comprises logical memory data and the second data comprises physical memory data.

26. The arrangement as claimed in claim 25, wherein the address decoding unit comprises:
a) a basic addressing section configured to address memory cells of the memory cell array with internal addressing data corresponding to first lines of the memory cell array; and
b) a redundant addressing section configured to address memory cells of the memory cell array with internal addressing data corresponding to redundant lines of the memory cell array.

27. The arrangement as claimed in claim 26, further comprising a first data line coupled between the basic addressing section and the memory cell array and a second data line coupled between the redundant addressing section and the memory cell array.

28. The arrangement as claimed in claim 28, wherein the memory data converter is operably coupled to the first data line and the second data line.

29. The arrangement as claimed in claim 20, wherein the memory data converter configured to convert first data received from the test system into second data, the memory data converter further configured to provide a memory data conversion in a manner dependent on the internal addressing data of the electronic circuit device, the internal addressing data including at least some address data representing a redirection away from a defective memory address.
